(19) United States
(12) Patent Application Publication
(10) Pub. No.: US 2024/0178221 A1
(43) Pub. Date: May 30, 2024

(54) SEMICONDUCTOR STRUCTURE OF SCHOTTKY DEVICES

(71) Applicant: MEDIATEK INC., Hsinchu City (TW)

(72) Inventors: Shih-Chuan CHIU, Hsinchu City (TW); Chia-Hsin HU, Hsinchu City (TW); Zheng ZENG, Hsinchu City (TW)

(21) Appl. No.: 18/502,225

(22) Filed: Nov. 6, 2023

Related U.S. Application Data
(60) Provisional application No. 63/385,445, filed on Nov. 30, 2022.

(51) Int. Cl. H01L 27/06; H01L 29/73; H01L 29/78; H01L 29/872

(52) U.S. Cl. CPC H01L 27/0623; H01L 27/0629; H01L 29/7308; H01L 29/7851; H01L 29/872

(57) ABSTRACT

Semiconductor structures of Schottky devices are provided. An N-type well region and a P-type well region are formed over a P-type semiconductor substrate. A first active region is formed over the P-type well region, and includes a plurality of first fins. A second active region is formed over the N-type well region, and includes a plurality of second fins. A third active region is formed over the N-type well region, and includes a plurality of third fins. A plurality of electrodes are formed over the third active region. The electrodes, the first source/drain features and the second source/drain features are formed in the same level. An emitter region of a Schottky BJT is formed by the electrodes, a base region of the Schottky BJT is formed by the N-type well region, and a collector region of the Schottky BJT is formed by the P-type semiconductor substrate.

### CROSS REFERENCE TO RELATED APPLICATIONS

This application claims the benefit of U.S. Provisional Application No. 63/385,445, filed Nov. 30, 2022, the entirety of which is incorporated by reference herein.

### BACKGROUND OF THE INVENTION

### Field of the Invention

The present invention relates to Schottky devices, and, in particular, to Schottky bipolar junction transistors (BJTs) and Schottky devices.

### Description of the Related Art

Bipolar junction transistors (BJTs), which can be formed using a CMOS compatible process, are key parts of analog integrated circuits such as band-gap voltage reference circuits. These circuits are often sensitive to the Vbe (base-emitter voltage) value and Vbe mismatch of BJT.

Furthermore, because of the advantages of having a majority of conduction carriers and a low turn-on voltage in a forward bias, Schottky BJTs and Schottky diodes are widely utilized to improve power transfer efficiency in integrated circuits (ICs).

### BRIEF SUMMARY OF THE INVENTION

An embodiment of the present invention provides a semiconductor structure. An N-type well region is formed over a P-type semiconductor substrate. A first P-type well region is formed over the P-type semiconductor substrate. A first active region is formed over the first P-type well region, and includes a plurality of first fins extending in a first direction and a plurality of first source/drain features epitaxially grown on the first fins. A second active region is formed over the N-type well region, and includes a plurality of second fins extending in the first direction and a plurality of second source/drain features epitaxially grown on the second fins. A third active region is formed over the N-type well region, and includes a plurality of third fins extending in the first direction. A plurality of electrodes are formed over the third active region, and each electrode extends in a second direction to contact the third fins. The second direction is perpendicular to the first direction. The electrodes, the first source/drain features and the second source/drain features are formed in the same level. An emitter region of a Schottky bipolar junction transistor (BJT) is formed by the electrodes, a base region of the Schottky BJT is formed by the N-type well region, and a collector region of the Schottky BJT is formed by the P-type semiconductor substrate.

Furthermore, an embodiment of the present invention provides a semiconductor structure. A well region is formed over a semiconductor substrate. A first active region is formed over the well region, and includes a plurality of first fins extending in a first direction and a plurality of first source/drain features epitaxially grown on the first fins. A second active region is formed over the well region, and includes a plurality of second fins extending in the first direction. A plurality of electrodes are formed over the second active region, and each electrode extends in a second direction to contact the second fins. The second direction is perpendicular to the first direction. The electrodes and the first source/drain features are formed in the same level. When the first source/drain features and the well region have N-type conductivity, an anode region of a Schottky diode is formed by the electrodes and a cathode region of the Schottky diode is formed by the well region. When the first source/drain features and the well region have P-type conductivity, the anode region of the Schottky diode is formed by the well region and the cathode region of the Schottky diode is formed by the electrodes.

### BRIEF DESCRIPTION OF THE DRAWINGS

The present invention can be more fully understood by reading the subsequent detailed description and examples with references made to the accompanying drawings, wherein:

FIG. 1 shows a top view of a Schottky bipolar junction transistor (BJT) structure according to some embodiments of the invention.

FIG. 2 shows a cross-sectional view of the Schottky BJT structure along line A-A′ of FIG. 1 according to some embodiments of the invention.

FIG. 3 shows an energy band diagram illustrating the energy depletion of the Schottky BJT device according to some embodiments of the invention.

FIG. 4 shows a top view of a Schottky diode structure according to some embodiments of the invention.

FIG. 5 shows a cross-sectional view of the Schottky diode along line B-B′ of FIG. 4 according to some embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Furthermore, spatially relative terms, such as “beneath,” “below,” “lower,” “above,” “upper” and the like, may be used herein for ease of description to describe one element or feature's relationship to another element(s) or feature(s) as illustrated in the figures.

Semiconductor devices employing higher device integration density, such as fin-base field effect transistor (FinFET) semiconductor devices. FinFET NMOS and/or PMOS transistors are formed in oxide definition (OD) regions. The OD region, sometimes labeled as an “oxide diffusion” area, defines an active region for the transistor, i.e., the region where the source, drain and channel under the gate of transistor are formed. The active region is defined to be between inactive areas, such as shallow trench isolation (STI) or field oxide (FOX) region.

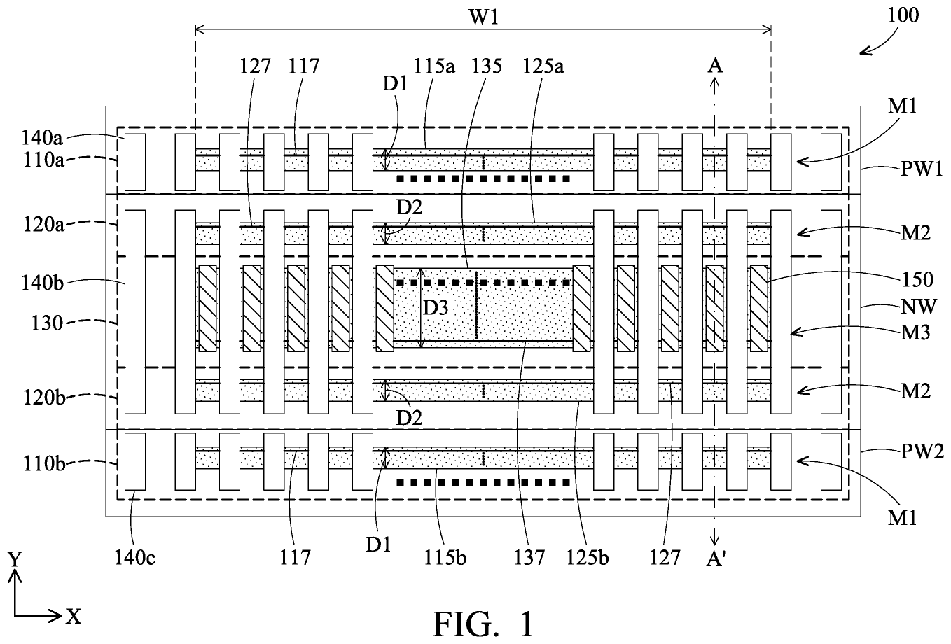

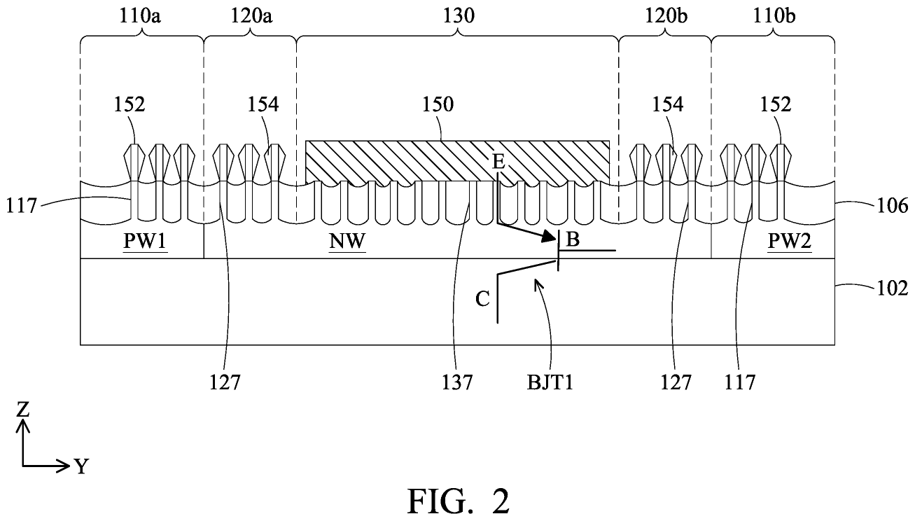

FIG. 1 shows a top view of a Schottky bipolar junction transistor (BJT) structure 100 according to some embodiments of the invention. The Schottky BJT structure 100 has a PNP BJT device BJT1 (shown in FIG. 2), and includes the first device regions 110a and 110b, the second device regions 120a and 120b and the third device region 130. The first device region 110a is formed over the P-type well region PW1, and the first device region 110b is formed over the P-type well region PW2. The second device regions 120a and 120b and the third device region 130 are formed over the N-type well region NW. The N-type well region is disposed between the P-type well regions PW1 and PW2.

The first device regions 110a and 110b include the active regions 115a and 115b, respectively. The active regions 115a and 115b have a length W1 in the X direction and a width D1 in the Y direction. Each of the active regions 115a and 115b includes a plurality of transistors M1, and the transistors M1 are formed by the fins 117 extending in the X direction. Furthermore, the number of fins 117 in the active regions 115a and 115b are the same. The gate structures 140a of the transistors M1 are formed over the P-type well region PW1 with a first pitch and extend in the Y direction. In some embodiments, the gate structures 140a are floating, i.e., no signal is applied to the gate of the transistors M1 over the P-type well region PW1. Similarly, the gate structures 140c of the transistors M1 are formed over the P-type well region PW2 with the first pitch and extend in the Y direction. In some embodiments, the gate structures 140b are floating, i.e., no signal is applied to the gate of the transistors M1 over the P-type well region PW2.

The second device regions 120a and 120b include the active regions 125a and 125b, respectively. The active regions 125a and 125b have a length W1 in the X direction and a width D2 in the Y direction. Each of the active regions 125a and 125b includes a plurality of transistors M2, and the transistors M2 are formed by the fins 127 extending in the X direction. Furthermore, the number of fins 127 in the active regions 125a and 125b are the same. In some embodiments, the fins 117 and the fins 127 have the same length in the X direction. In some embodiments, the width D2 of the active regions 125a and 125b is equal to the width D1 of the active regions 115a and 115b, and the number of fins 117 is equal to the number of fins 127. The gate structures 140b of the transistors M2 are formed over the N-type well region NW with the first pitch and extend in the Y direction. In some embodiments, the gate structures 140b are floating, i.e., no signal is applied to the gate of the transistors M2 in the active regions 125a and 125b.

The third device region 130 includes the active region 135. The active region 135 has a length W1 in the X direction and a width D3 in the Y direction. The active region 135 includes a plurality of transistors M3, and the transistors M3 are formed by the fins 137 extending in the X direction. In some embodiments, the fins 117, the fins 127 and the fins 137 have the same length in the X direction. In some embodiments, the width D3 of the active region 130 is greater than the width D1 of the active regions 110a and 110b and the width D2 of the active regions 120a and 120b, and the number of fins 137 is greater than the number of fins 117 and the number of fins 127. In some embodiments, the number of fins 137 is equal to the sum of the number of fins 117 and 127. The gate structures 140b of the transistors M3 in the active region 135 are shared with the transistors M2 in the active regions 125a and 125. In some embodiments, the gate structures 140b are floating, i.e., no signal is applied to the gate of the transistors M2 in the active regions 125a and 125b and the gate of the transistors M3 in the active region 135.

The third device region 130 further includes the electrodes 150 extending in the Y direction. Each electrode 150 is formed over the active region 135 and between two adjacent gate structures 140b. The electrodes 150 are separated from the gate structures 140b. In the Y direction, the length of the electrodes 150 is shorter than that of the gate structures 140b. Furthermore, the electrodes 150 are formed under the interconnect structure including the metal layers and the via layers. The electrodes 150 may include a metal material, such as Ti, Co, W, Ni, combinations thereof, or other suitable material.

In the Schottky BJT structure 100, the active region 135 is disposed between the active regions 125a and 125b. Moreover, the active region 125a is disposed between the active regions 115a and 135, and the active region 125b is disposed between the active regions 115b and 135. In other words, the Schottky BJT structure 100 has a symmetrical structure in layout. In such embodiment, the number of active regions 125a and 125b is equal to the number of active regions 115a and 115b. Moreover, the transistors formed in the active regions 115a, 115b, 125a, 125b and 135 are regular fin-base transistors (e.g., the fins with fixed widths). In some embodiments, the transistors in the active regions of the Schottky BJT structure 100 may be non-regular fin field effect transistors (FinFETs) (e.g., the fins with various widths).

FIG. 2 shows a cross-sectional view of the Schottky BJT structure 100 along line A-A′ of FIG. 1 according to some embodiments of the invention. The N-type well region NW and the P-type well regions PW1 and PW2 are formed over a semiconductor substrate 102. The N-type well region NW is disposed between the P-type well regions PW1 and PW2. Moreover, the bottom surfaces of the N-type well region NW and the P-type well regions PW1 and PW2 are coplanar. In some embodiments, the semiconductor substrate 102 is a Si substrate, i.e., P-type substrate. In some embodiments, the material of the semiconductor substrate 102 is selected from a group consisting of bulk-Si, SiP, SiGe, SiC, SiPC, Ge, SOI-Si, SOI-SiGe, III-VI material, or a combination thereof.

In FIG. 2, the fins 117 of the first device regions 110a and 110b are formed over the P-type well regions PW1 and PW2, and the fins 117 are separated from each other by the STI 106. The source/drain features 152 of the transistors M1 are epitaxially grown on the fins 117. In some embodiments, the epitaxially-grown materials of the source/drain features 152 may include the materials with P-type conductivity, such as SiGe, SiGeC, Ge, Si, boron-doped SiGe, gallium-doped SiGe, boron and gallium doped SiGe, boron and carbon doped SiGe, or a combination thereof. Furthermore, the source/drain features 152 in the first device region 110a and 110b are electrically connected together by the upper interconnection structure.

The fins 127 of the second device regions 120a and 120b are formed over the N-type well region NW, and the fins 127 are separated from each other by the STI 106. The source/drain features 154 of the transistors M2 are epitaxially grown on the fins 127. In some embodiments, the epitaxially-grown materials of the source/drain features 154 may include the materials with N-type conductivity, such as SiP, SiC, SiPC, SiAs, Si, antimony-doped SiP (SiP:Sb), antimony-doped SiAs (SiAs:Sb), or a combination thereof. Furthermore, the source/drain features 154 in the second device region 120a and 120b are electrically connected together by the upper interconnection structure.

The fins 137 of the third device region 130 are formed over the N-type well region NW, and the fins 137 are separated from each other by the STI 106. Compared with the first device regions 110a and 110b and the second device regions 120a and 120b, there is no source/drain features epitaxially grown on the fins 137 in the third device region 130, i.e., the third device region 130 and the transistors M3 are free of source/drain features. In the Schottky BJT structure 100, the electrode 150 is formed on and in contact with the fins 137 of the third device region 130. The electrode 150 extends in the Y direction to overlap all of the fins 137 in the Z direction. It should be noted that the electrode 150 and the source/drain features 152 and 154 are formed in the same level. In some embodiments, the electrode 150 may be the connecting feature that is conductive.

In some embodiments, the number of fins 117 in each of the first device regions 110a and 110b is equal to the number of fins 127 in each of the second device regions 120a and 120b. Moreover, the number of fins 137 in the third device region 130 is greater than the number of fins 127 in the second device regions 120a and 120b and the number of fins 117 in the first device regions 110a and 110b.

There are two basic types of bipolar transistor structures, PNP and NPN, which basically describe the physical arrangement of the P-type and N-type semiconductor materials from which they are made. In such embodiment, the Schottky BJT device BJT1 is the PNP-type BJT device. In some embodiments, the Schottky BJT device BJT1 may be the NPN-type BJT device by modifying the semiconductor materials and adding the required semiconductor layer in the semiconductor structure of the Schottky BJT structure 100.

In the Schottky BJT structure 100, the emitter region of the Schottky BJT device BJT1 is formed by the electrodes 150 in the third device region 130, the base region of the Schottky BJT device BJT1 is formed by the N-type well region NW, and the collector region of the Schottky BJT device BJT1 is formed by the semiconductor substrate 102. In other words, one PN junction of the Schottky BJT device BJT1 is formed between the electrodes 150 and the N-type well region NW, and another PN junction of the Schottky BJT device BJT1 is formed between the N-type well region NW and the semiconductor substrate 102. Moreover, the emitter region of the Schottky BJT device BJT1 is electrically coupled to the upper interconnect structure (not shown) over the electrodes 150. The base region of the Schottky BJT device BJT1 is electrically coupled to the upper interconnect structure (not shown) through the fins 127 and the source/drain features 154 of the transistors M2. The collector region of the Schottky BJT device BJT1 is electrically coupled to the upper interconnect structure (not shown) through the P-type well regions PW1 and PW2, and the fins 117 and the source/drain features 152 of the transistors M1.

Compared with traditional BJT device that using P-type source/drain features as the emitter region, the emitter region of the Schottky BJT device BJT1 in the Schottky BJT structure 100 is formed by the electrodes 150 with lower energy level, thereby the Schottky BJT device BJT1 has low turned-on Vbe voltage. The Schottky BJT device BJT1 of the Schottky BJT structure 100 can be used in the circuits for low-power applications.

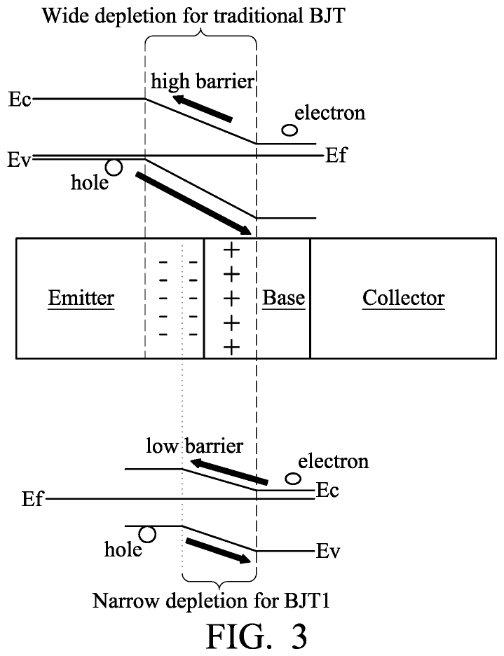

FIG. 3 shows an energy band diagram illustrating the energy depletion of the Schottky BJT device BJT1 according to some embodiments of the invention. In FIG. 3, Ef is the Fermi surface in the metal-semiconductor junction, Ec is the conduction band, and Ev is the valance band. Because the electrodes 150 and the N-type well region NW form a Schottky diode with a low barrier for electrons to transport in the Schottky BJT device BJT1, the Schottky BJT device BJT1 has a narrower depletion in the PN junction of the Schottky diode than a traditional BJT device. Therefore, the Schottky BJT device BJT1 has low turn on voltage accompanied with low power consumption.

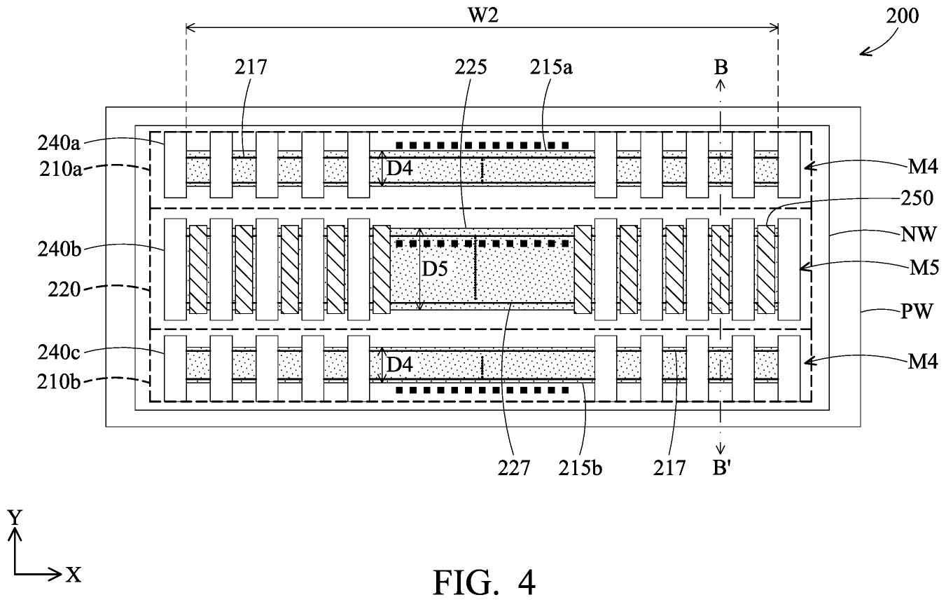

FIG. 4 shows a top view of a Schottky diode structure 200 according to some embodiments of the invention. The Schottky diode structure 200 includes the first device regions 210a and 210b and the second device region 220. The first device regions 210a and 210b and the second device region 220 are formed over the N-type well region NW, and the N-type well region NW is surrounded by the P-type well region PW. The second device region 220 is disposed between the first device regions 210a and 210b. In other words, the first device regions 210a and 210b are disposed on opposite sides of the second device region 220.

The first device regions 210a and 210b include the active regions 215a and 215b, respectively. The active regions 215a and 215b have a length W2 in the X direction and a width D4 in the Y direction. Each of the active regions 215a and 215b includes a plurality of transistors M4, and the transistors M4 are formed by the fins 217 extending in the X direction. Furthermore, there are the same number of fins 217 in the active regions 215a and 215b. The gate structures 240a of the transistors M4 are formed over the active region 215a with the first pitch and extend in the Y direction. In some embodiments, the gate structures 240a are floating, i.e., no signal is applied to the gate of the transistors M4 over the active region 215a. Similarly, the gate structures 240c of the transistors M4 are formed over the active region 215b with the first pitch and extend in the Y direction. In some embodiments, the gate structures 240c are floating, i.e., no signal is applied to the gate of the transistors over the active region 215b.

The second device region 220 include the active region 225. The active region 225 has a length W2 in the X direction and a width D5 in the Y direction. The active region 225 includes a plurality of transistors M5, and the transistors M5 are formed by the fins 227 extending in the X direction. In some embodiments, the fins 217 and the fins 227 have the same length in the X direction. In some embodiments, the width D4 of the active regions 225a and 225b is less than the width D5 of the active region 225, and the number of fins 217 is less than the number of fins 227. The gate structures 240b of the transistors M5 are formed over the active region 225 with the first pitch and extend in the Y direction. In some embodiments, the gate structures 240b are floating, i.e., no signal is applied to the gate of the transistors M5 in the active region 225.

The second device region 220 further includes the electrodes 250 extending in the Y direction. Each electrode 250 is formed over the active region 225 and between two adjacent gate structures 240b. The electrodes 250 are separated from the gate structures 240b. In the Y direction, the length of the electrodes 250 is shorter than that of the gate structures 240b. Furthermore, the electrodes 250 are formed under the interconnect structure including the metal layers and the via layers. The electrodes 250 may include a metal material, such as Ti, Co, W, Ni, combinations thereof, or other suitable material.

In the Schottky diode structure 200, the active region 225 is disposed between the active regions 215a and 215b. In other words, the Schottky diode structure 200 has a symmetrical structure in layout. Moreover, the transistors formed in the active regions 215a, 215b and 225 are regular fin-base transistors (e.g., the fins with fixed widths). In some embodiments, the transistors in the active regions of the Schottky diode structure 200 may be non-regular fin field effect transistors (FinFETs) (e.g., the fins with various widths).

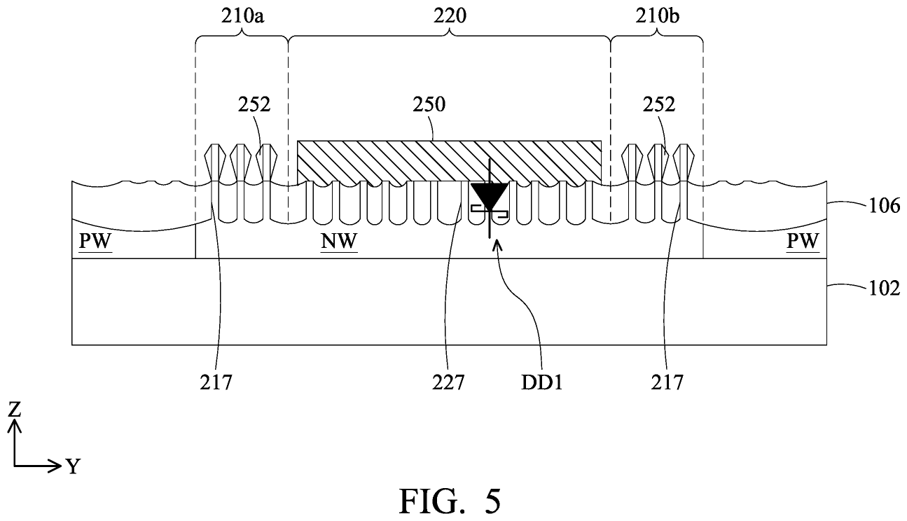

FIG. 5 shows a cross-sectional view of the Schottky diode 200 along line B-B′ of FIG. 4 according to some embodiments of the invention. The N-type well region NW and the P-type well region PW are formed over the semiconductor substrate 102. The N-type well region NW is surrounded by the P-type well region PW. Moreover, the bottom surfaces of the N-type well region NW and the P-type well region PW are coplanar. In some embodiments, the semiconductor substrate 102 is a Si substrate, i.e., P-type substrate. In some embodiments, the material of the semiconductor substrate 102 is selected from a group consisting of bulk-Si, SiP, SiGe, SiC, SiPC, Ge, SOI-Si, SOI-SiGe, III-VI material, or a combination thereof.

In FIG. 5, the fins 217 of the first device regions 110a and 110b are formed over the N-type well region NW, and the fins 217 are separated from each other by the STI 106. The source/drain features 252 of the transistors M4 are epitaxially grown on the fins 217. In some embodiments, the epitaxially-grown materials of the source/drain features 252 may include the materials with N-type conductivity, such as SiP, SiC, SiPC, SiAs, Si, antimony-doped SiP (SiP:Sb), antimony-doped SiAs (SiAs:Sb), or a combination thereof. Furthermore, the source/drain features 252 in the first device region 210a and 210b are electrically connected together by the upper interconnection structure.

The fins 227 of the second device region 220 are formed over the N-type well region NW, and the fins 227 are separated from each other by the STI 106. Compared with the first device regions 210a and 210b, there is no source/drain features epitaxially grown on the fins 227 in the second device region 220, i.e., the second device region 220 and the transistors M5 are free of source/drain features. In the Schottky diode structure 200, the electrode 250 is formed on and in contact with the fins 227 of the second device region 220. The electrode 250 extends in the Y direction to overlap all of the fins 227 in the Z direction. It should be noted that the electrode 250 and the source/drain features 252 are formed in the same level. In some embodiments, the electrode 250 may be the connecting feature that is conductive.

In some embodiments, the number of fins 217 in the first device region 210a is equal to the number of fins 217 in the first device region 210b. Moreover, the number of fins 227 in the second device region 220 is greater than the number of fins 217 in the first device regions 210a and 210b.

In the Schottky diode structure 200, the anode region of the diode device DD1 is formed by the electrodes 250 in the second device region 220, and the cathode region of the diode device DD1 is formed by the N-type well region NW. In other words, one PN junction of the diode device DD1 is formed between the electrodes 250 and the N-type well region NW. Moreover, the anode region of the Schottky diode device DD1 is electrically coupled to the upper interconnect structure (not shown) over the electrodes 150. The cathode region of the Schottky diode device DD1 is electrically coupled to the upper interconnect structure (not shown) through the fins 217 and the source/drain features 252 of the transistors M4.

In some embodiments, by interchanging the semiconductor materials and/or adding the required semiconductor layer in the semiconductor structure of the Schottky diode structure 200 (e.g., the N-type well region NW is replaced with the P-type well region PW and the epitaxially-grown materials of the source/drain features 252 include the materials with P-type conductivity), the cathode region of the diode device DD1 is formed by the electrodes 250, and the anode region of the diode device DD1 is formed by the P-type well region PW.

Compared with traditional diode devices that use P-type source/drain features as the anode region, the anode region of the Schottky diode device DD1 in the Schottky diode structure 200 is formed by the electrodes 250 with a lower energy level. Thereby, the Schottky diode device DD1 has a fast switching speed and low turned-on Vbe voltage for high current. Therefore, the Schottky diode device DD1 of the Schottky diode structure 200 can be used in circuits for low-power applications.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a P-type semiconductor substrate;
an N-type well region formed over the P-type semiconductor substrate;
a first P-type well region formed over the P-type semiconductor substrate;
a first active region formed over the first P-type well region, comprising a plurality of first fins extending in a first direction and a plurality of first source/drain features epitaxially grown on the first fins;
a second active region formed over the N-type well region, comprising a plurality of second fins extending in the first direction and a plurality of second source/drain features epitaxially grown on the second fins; and
a third active region formed over the N-type well region, comprising a plurality of third fins extending in the first direction; and
a plurality of electrodes formed over the third active region, each extending in a second direction to contact the third fins, wherein the second direction is perpendicular to the first direction,
wherein the electrodes, the first source/drain features and the second source/drain features are formed in the same level,
wherein an emitter region of a Schottky bipolar junction transistor (BJT) is formed by the electrodes, a base region of the Schottky BJT is formed by the N-type well region, and a collector region of the Schottky BJT is formed by the P-type semiconductor substrate.

2. The semiconductor structure as claimed in claim 1, wherein the third active region is free of source/drain features epitaxially grown on the third fins.

3. The semiconductor structure as claimed in claim 1, wherein the electrodes include Ti, Co, W or Ni.

4. The semiconductor structure as claimed in claim 1, wherein the first source/drain features comprise epitaxially-grown materials with P-type conductivity, and the second source/drain features comprise epitaxially-grown materials with N-type conductivity.

5. The semiconductor structure as claimed in claim 1, wherein in the first direction, the first active region, the second active region and the third active region have the same width.

6. The semiconductor structure as claimed in claim 1, wherein in the second direction, the first active region and the second active region are shorter than the third active region.

7. The semiconductor structure as claimed in claim 1, wherein the number of the third fins is greater than the number of the first fins and the number of the second fins.

8. The semiconductor structure as claimed in claim 1, wherein the number of the third fins is equal to the sum of the number of the first fins and the second fins.

9. The semiconductor structure as claimed in claim 1, further comprising:
a fourth active region formed over the N-type well region, comprising a plurality of fourth fins extending in the first direction and a plurality of third source/drain features epitaxially grown on the fourth fins,
wherein the third active region is disposed between the second and fourth active regions.

10. The semiconductor structure as claimed in claim 9, wherein the number of the fourth fins is equal to the number of the second fins, and the third source/drain features comprise epitaxially-grown materials with N-type conductivity and are electrically connected to the second source/drain features.

11. The semiconductor structure as claimed in claim 9, further comprising:
a second P-type well region formed over the P-type semiconductor substrate;
a fifth active region formed over the second P-type well region, comprising a plurality of fifth fins extending in the first direction and a plurality of fourth source/drain features epitaxially grown on the fifth fins,
wherein the N-type well region is disposed between the first and second P-type well regions.

12. The semiconductor structure as claimed in claim 11, wherein the number of the fifth fins is equal to the number of the first fins, and the fourth source/drain features comprise epitaxially-grown materials with P-type conductivity and are electrically connected to the first source/drain features.

13. A semiconductor structure, comprising:
a semiconductor substrate;
a well region formed over the semiconductor substrate;
a first active region formed over the well region, comprising a plurality of first fins extending in a first direction and a plurality of first source/drain features epitaxially grown on the first fins;
a second active region formed over the well region, comprising a plurality of second fins extending in the first direction; and
a plurality of electrodes formed over the second active region, each extending in a second direction to contact the second fins, wherein the second direction is perpendicular to the first direction,
wherein the electrodes and the first source/drain features are formed in the same level,
wherein when the first source/drain features and the well region have N-type conductivity, an anode region of a Schottky diode is formed by the electrodes and a cathode region of the Schottky diode is formed by the well region,
wherein when the first source/drain features and the well region have P-type conductivity, the anode region of the Schottky diode is formed by the well region and the cathode region of the Schottky diode is formed by the electrodes.

14. The semiconductor structure as claimed in claim 13, wherein the second active region is free of source/drain features epitaxially grown on the second fins.

15. The semiconductor structure as claimed in claim 13, wherein the electrodes include Ti, Co, W or Ni.

16. The semiconductor structure as claimed in claim 13, wherein in the first direction, the first active region and the second active region have the same width.

17. The semiconductor structure as claimed in claim 13, wherein in the second direction, the first active region is shorter than the second active region.

18. The semiconductor structure as claimed in claim 13, wherein the number of the second fins is greater than the number of the first fins.

19. The semiconductor structure as claimed in claim 13, further comprising:
a third active region formed over the well region, each comprising a plurality of third fins extending in the first direction and a plurality of second source/drain features epitaxially grown on the third fins,
wherein the second active region is disposed between the first and third active regions.

20. The semiconductor structure as claimed in claim 19, wherein the number of the third fins is equal to the number of the first fins, and the first and second source/drain features have the same type of conductivity and are electrically connected together.
